(19) United States
(12) Patent Application Publication
(10) Pub. No.: US 2008/0296148 A1
(43) Pub. Date: Dec. 4, 2008

(54) Method for fabricating concentration-gradient high-frequency ferromagnetic films

(75) Inventors: Shan-Dong Li, Hsinchu City (TW); Jenq-Gong Duh, Hsinchu City (TW); Yung-Wang Peng, Taipei County (TW); Cheng-Lun Kuo, Tainan County (TW)

Correspondence Address: Joe McKinney Muncy, PO Box 1364, Fairfax, VA, 22038-1364, US

(73) Assignee: National Tsing Hua University

(21) Appl. No.: 11/806,796

(22) Filed: Jun. 4, 2007

(51) Int. Cl. C23C 14/00

(52) U.S. Cl. 204/192.1

(57) ABSTRACT

The present invention discloses a method for fabricating concentration-gradient high-frequency ferromagnetic film, wherein the primary material target is arranged exactly below the sputter-coated substrate to achieve the on-substrate concentration uniformity of the components coming from the primary material target; at least one doping target is arranged at a position deviating from the center of the substrate to create a doping concentration gradient on the substrate along a direction, and a stress gradient is thus created on the substrate along the direction of concentration variation. Thus, the as-deposited ferromagnetic material fabricated at ambient temperature can possess the uniaxial anisotropy that a high-frequency ferromagnetic material needs.

### FIELD OF THE INVENTION

The present invention relates to a method for fabricating a high-frequency ferromagnetic film, particularly to a method for fabricating a concentration-gradient high-frequency ferromagnetic film.

### BACKGROUND OF THE INVENTION

The communication-related IC has persistently advanced with the development of the communication market, and more and more manufacturers adopt SOC (system-on-chip) to fabricate products. However, not all elements are suitable be integrated into a single chip.

As a ferromagnetic planar inductor can increase the inductance, reduce the size and promote the performance, the integration technology of a high-frequency ferromagnetic film and a planar inductor has been extensively used in the integration process of passive elements recently. At present, ferromagnetic planar inductors have been widely applied to DC-DC converters, filters, modulators and phase shifters.

In applications mentioned above, the high-frequency performance of a ferromagnetic film is a critical factor in the integration process. The ferromagnetic material usually needs high magnetization intensity and a uniaxial anisotropy. Thus, an iron-cobalt-based material is usually adopted as the ferromagnetic material and heat-treated at a temperature of between 300 and 600□ to create a uniaxial anisotropy. However, in addition to increasing the fabrication cost, the higher temperature of the heat treatment is incompatible with the conventional integration process of a silicon substrate because the temperature of the heat treatment will damage other elements or even make the entire fabrication process impossible.

### SUMMARY OF THE INVENTION

The primary objective of the present invention is to provide a method for fabricating a uniaxial-anisotropy high-frequency ferromagnetic film at ambient temperature without using a heat treatment.

Another objective of the present invention is to provide a method for fabricating a high-frequency ferromagnetic film at ambient temperature to solve the conventional problem that the process of fabricating a ferromagnetic film is incompatible with the processes of fabricating other elements.

To achieve objectives mentioned above, the present invention proposes a method for fabricating a composition-gradient high-frequency ferromagnetic film, which comprises the following steps: arranging the primary material target exactly below the sputter-coated substrate to achieve the on-substrate concentration uniformity of the components coming from the primary material target; and arranging at least one doping target at a position deviating from the center of the substrate to create a doping concentration gradient on the substrate along a direction.

The components of the primary material target are selected from ferromagnetic materials. The ferromagnetic material may be iron, cobalt or nickel. Alternatively, the ferromagnetic material may be a ferromagnetic alloy, such as an alloy of magnetic transition metals or an alloy of transition metals and rare earth elements. Further, the components of the primary material target may be selected from non-metal magnetic materials. The non-metal magnetic materials are magnetic oxides, such as ferrite. The components of the doping target are selected from metals, oxides, nitrides and borides.

The present invention utilizes the gradient sputtering technology, which arranges the doping target at a position deviating from the center of the substrate, to perform the sputtering of a doping (such as a metal, an oxide, a nitride or a boride) and create a doping concentration gradient on the substrate along a direction. Thus, a stress gradient is created on the substrate along the direction of concentration variation. Thereby, the as-deposited ferromagnetic material fabricated at ambient temperature can possess the uniaxial anisotropy that a high-frequency ferromagnetic material needs.

### BRIEF DESCRIPTION OF THE DRAWINGS

FIG. 1 is a diagram schematically showing the method for fabricating concentration-gradient high-frequency ferromagnetic film according to the present invention.

FIG. 2 is a diagram schematically showing a concentration-gradient high-frequency ferromagnetic film fabricated according to the present invention.

FIG. 3 is a diagram showing the Al concentration distribution on a substrate.

FIG. 4 is a diagram showing the magnetization intensity of a sample having a composition Fe_{39.3}CO_{43.2}Al_{2.4}O_{15.1}.

FIG. 5 is a diagram showing the relationship between the magnetic response and the frequency of a sample having a composition Fe_{39.3}CO_{43.2}Al_{20.4}O₁₅.

FIG. 6 is a diagram showing the Hf concentration distribution on a substrate.

FIG. 7 is a diagram showing the magnetization intensity of a sample having a composition Fe_{48.5}CO_{20.7}Hf_{10.9}N_{19.9}.

FIG. 8 is a diagram showing the relationship between the magnetic response and the frequency of a sample having a composition Fe_{48.5}Co_{20.7}Hf_{10.9}N_{19.9}.

### DETAILED DESCRIPTION OF THE PREFERRED EMBODIMENTS

The technical contents of the present invention will be described in detail with the embodiments. It is to be noted that those embodiments are only to exemplify the present invention but not to limit the scope of the present invention.

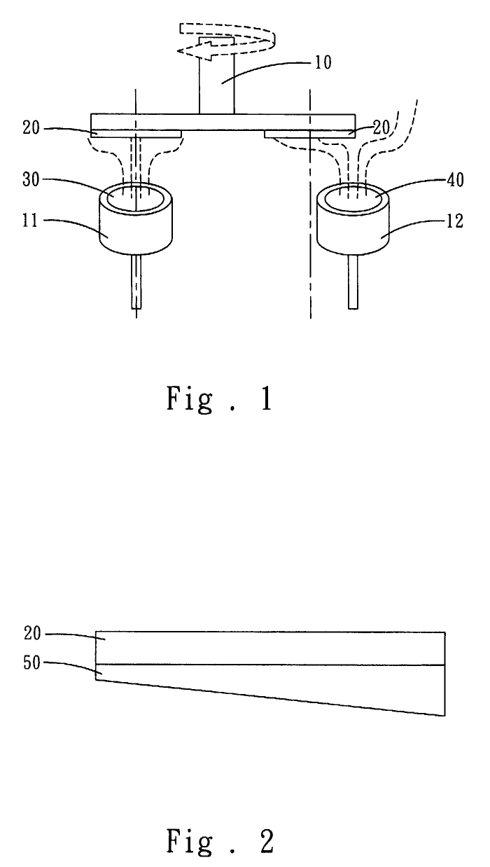

The present invention is realized with a vacuum sputtering process. Refer to FIG. 1. A substrate 20, which is to be sputter-coated, is arranged on a sputtering table 10. A target holder 11 holding a primary material target 30 is arranged exactly below the substrate 20 to achieve the on-substrate concentration uniformity of the components coming from the primary materials. A target holder 12 holding a doping target 40 is arranged at a position deviating from the center of the substrate 20 to create a doping concentration gradient on the substrate 20 along a direction. Refer to FIG. 2. The concentrations of the components coming from the doping target 40 increase along a direction in the sputter-coated film 50 (containing the components of the primary material target 30 and the doping target 40) on the substrate 20.

The components of the primary material target 30 are selected from ferromagnetic materials. The ferromagnetic materials may be iron, cobalt or nickel. Alternatively, the ferromagnetic material may be a ferromagnetic alloy, such as an alloy of magnetic transition metals or an alloy of transition metals and rare earth elements. Further, the components of the primary material target may be selected from non-metal magnetic materials. The non-metal magnetic materials are magnetic oxides, such as ferrite. The components of the doping target 40 are selected from metals, oxides, nitrides and borides.

Below, the existing high-frequency ferromagnetic materials FeCo-oxides and FeCoMN are used to exemplify the present invention. The composition expression of FeCo-oxides is FeₓCo_{y}-Q_{z}, wherein x=40˜80; y=20˜50; x+y+z=100; Q=Al₂O₃, SiO₂, TiO₂, or Ta₂O₅, which is attained via sputtering the doping target 40. However, the concentration of an oxide in the sputter-coated film is not necessarily equal to the concentration of the oxide in the doping target 40. The composition expression of FeCoMN is FeₓCo_{y}M_{z}Nᵥ, wherein x=40˜80; y=20˜50; v=2˜40; x+y+z+v=100; M=Hf, Zr, Nb, V, Mo, W, Cr, or Ta. The numerical values mentioned above refer to atom percentage.

According to the method of the present invention, the primary material target 30—FeCo is arranged exactly below the substrate 20 to achieve the concentration uniformity of iron and cobalt on the substrate 20. At least one doping target 40, such as a metal target or an oxide target, is arranged at a position deviating from the center of the substrate 20 to create a doping concentration gradient on the substrate 20 along a direction. If a nitride is to be sputtered, an appropriate proportion of the mixture gas of nitrogen and argon can be added into the reaction chamber.

Below, the characteristics and properties of two samples having typical compositions are used to demonstrate the efficacy of the present invention.

Composition 1—the (FeₓCo_{y})_{z}—(AlᵤOᵥ)_{w} system: The material system adopts a Fe₅₀CO₅₀ target as the primary material target 30 and an Al₂O₃ target as the doping target 40, and the film is formed via RF (Radio Frequency) gradient sputtering under an Ar-containing environment. In this example, the sputtering powers of the two targets are respectively 60 W and 60 W. The concentration gradient on the substrate 20 is detected with FE-EPMA (Field Emission Electron Probe Micro-Analyzer), and the measurement result is shown in the table below.

| Distance | | | | |
|---|---|---|---|---|
| from S to E (mm) | Fe (at. %) | Co (at. %) | Al (at. %) | O (at. %) |
| 2.5 | 36.38 | 42.55 | 3.29 | 17.78 |
| 7.5 | 37.64 | 42.08 | 3.00 | 17.28 |
| 12.5 | 39.63 | 42.05 | 2.50 | 15.83 |
| 17.5 | 38.91 | 42.69 | 2.43 | 15.97 |
| 22.5 | 38.92 | 43.70 | 2.29 | 15.09 |
| 27.5 | 40.11 | 43.10 | 2.06 | 14.73 |
| 32.5 | 40.72 | 42.86 | 1.90 | 14.52 |
| 37.5 | 40.85 | 43.25 | 1.81 | 14.10 |
| 42.5 | 40.04 | 44.48 | 1.74 | 13.74 |
| 47.5 | 40.72 | 44.03 | 1.65 | 13.60 |

The distance from S to E is measured on the substrate 20 along the direction from the edge of the sputtering table 10 toward the center of the sputtering table 10.

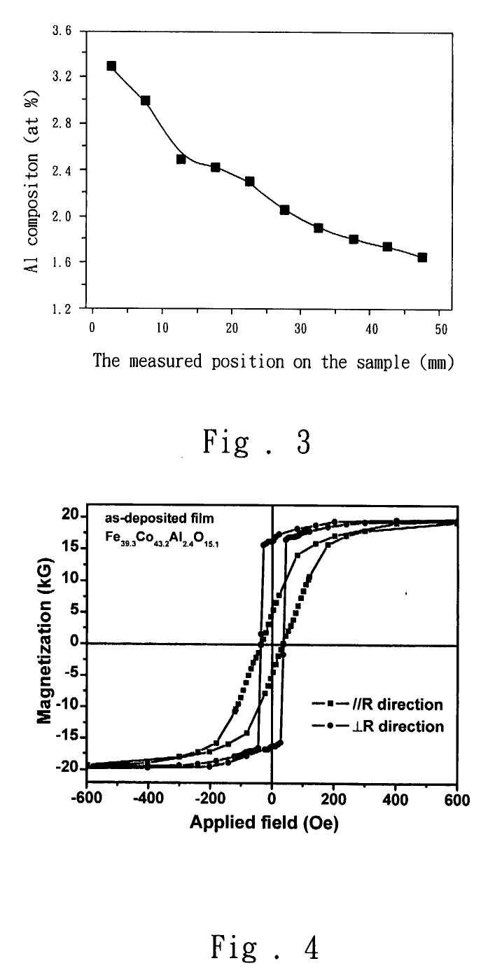

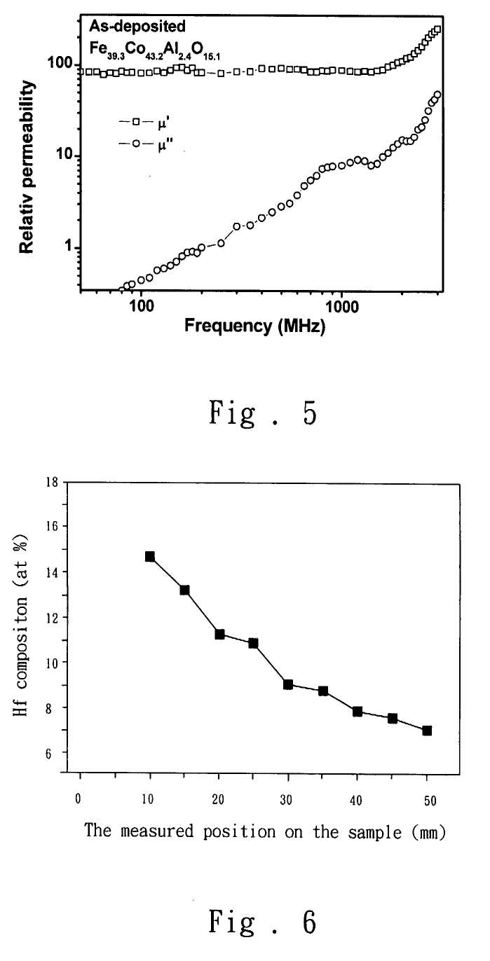

Refer to FIG. 3 a diagram showing the distribution of Al concentribution from S to E (measured along the direction from the edge of the sputtering table to the center of the sputtering table). From FIG. 3, it is observed: Al concentration decreases continuously from the edge to the center, i.e. there is an Al concentration gradient on the substrate 20. The as-deposited sample having a typical composition Fe_{39.3}CO_{43.2}Al_{2.4}O_{15.1} is tested with a VSM (Vibration Sample Magnetometer) and a high-frequency permeameter. The test results are respectively shown in FIG. 4 and FIG. 5. From FIG. 4, it is observed: The as-deposited substrate 20 has an obvious uniaxial anisotropy, i.e. there is a very great anisotropic field (over 100 Oe) along the radial direction, and saturation magnetization is easily attained in the direction vertical to the radius direction. FIG. 5 is a diagram showing the magnetic spectrum of the as-deposited sample having a typical composition Fe_{39.3}CO_{43.2}Al_{2.4}O_{15.1}. From FIG. 5, it is observed that the sample can reach a resonance frequency over 3 GHz, and the relative permeability thereof is over 100. The test results indicate that the material of the (FeₓCo_{y})_{z}—(AlᵤOᵥ)_{w} system fabricated according to the present invention has superior magnetic properties and high-frequency magnetic performance.

Composition 2—the (FeₓCo_{y})_{z}HfᵤNᵥ system: The material system adopts a Fe₇₀CO₃₀ target as the primary material target 30 and an Hf target as the doping target 40, and the film is formed via RF (Radio Frequency) gradient sputtering under an N₂/Ar-containing environment. In this example, the sputtering powers of the two targets are respectively 60 W and 100 W. The concentration gradient on the substrate 20 is detected with FE-EPMA (Field Emission Electron Probe Micro-Analyzer), and the measurement result is shown in the table below.

| Distance | | | | |
|---|---|---|---|---|
| from S to E (mm) | Fe (at. %) | Co (at. %) | Hf (at. %) | N (at. %) |
| 10 | 44.24 | 19.22 | 14.71 | 21.82 |
| 15 | 45.40 | 19.20 | 13.20 | 22.20 |
| 20 | 46.20 | 20.60 | 11.30 | 21.90 |
| 25 | 48.45 | 20.74 | 10.87 | 19.94 |
| 30 | 49.60 | 20.84 | 9.12 | 20.44 |
| 35 | 49.25 | 22.12 | 8.81 | 19.82 |
| 40 | 51.50 | 22.00 | 7.90 | 18.60 |
| 45 | 51.95 | 22.52 | 7.61 | 17.92 |
| 50 | 51.70 | 21.24 | 7.11 | 19.94 |

The distance form S to E is measured on the substrate 20 along the direction from the edge of the sputtering table 10 toward the center of the same.

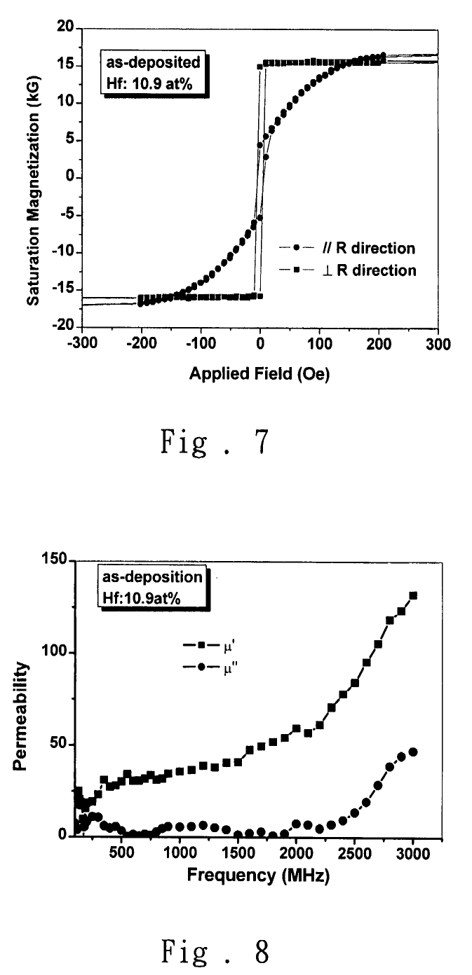

Refer to FIG. 6 a diagram showing the distribution of Hf concentribution from S to E (measured along the direction from the edge of the sputtering table to the center of the sputtering table). From FIG. 6, it is observed: Hf concentration decreases continuously from the edge to the center, i.e. there is an Hf concentration gradient on the substrate 20. The as-deposited sample having a typical composition Fe_{48.5}CO_{20.7}Hf_{10.9}N_{19.9} is tested with a VSM (Vibration Sample Magnetometer) and a high-frequency permeameter. Test results are respectively shown in FIG. 7 and FIG. 8. From FIG. 7, it is observed: The as-deposited substrate 20 has an obvious uniaxial anisotropy, i.e. there is a very great anisotropic field (over 150 Oe) along the radial direction, and saturation magnetization is easily attained in the direction vertical to the radius direction. FIG. 8 is a diagram showing the magnetic spectrum of the as-deposited sample with a typical composition Fe_{48.5}Co_{20.7}Hf_{10.9}N_{19.9}. From FIG. 8, it is observed: The sample can reach a resonance frequency over 3 GHz, and the relative permeability thereof is over 100 at near 3 GHz. Test results indicate that the material of the (FeₓCo_{y})_{z}HfᵤNᵥ system fabricated according to the present invention has superior magnetic properties and high-frequency magnetic performance.

From the experimental results of two material systems mentioned above, it is known that the concentration-gradient high-frequency ferromagnetic film fabricated with the method of the present invention has a saturation magnetization (Ms) of between 12 and 25 kG, a uniaxial anisotropic field of between 50 and 400 Oe or more and a self-resonance frequency of near 3 GHz or more according to the concentration of the doping.

Those described above are only the preferred embodiments to exemplify the present invention but not to limit the scope of the present invention. Any equivalent modification or variation according to the spirit of the present invention is to be also included within the scope of the present invention.

What is claimed is:

1. A method for fabricating a concentration-gradient high-frequency ferromagnetic film, which is realized with a vacuum sputtering method, comprising:
arranging a primary material target exactly below a sputter-coated substrate to achieve the on-substrate concentration uniformity of the components coming from said primary material target; and arranging at least one doping target at a position deviating from the center of said substrate to create a doping concentration gradient on said substrate along a direction.

2. The method for fabricating a concentration-gradient high-frequency ferromagnetic film according to claim 1, wherein the components of said primary material target are selected from ferromagnetic materials.

3. The method for fabricating a concentration-gradient high-frequency ferromagnetic film according to claim 2, wherein said ferromagnetic material is selected from the group consisting of iron, cobalt and nickel.

4. The method for fabricating a concentration-gradient high-frequency ferromagnetic film according to claim 2, wherein said ferromagnetic material is a ferromagnetic alloy.

5. The method for fabricating a concentration-gradient high-frequency ferromagnetic film according to claim 4, wherein said ferromagnetic alloy is an alloy of magnetic transition metals or an alloy of transition metals and rare earth elements.

6. The method for fabricating a concentration-gradient high-frequency ferromagnetic film according to claim 2, wherein said ferromagnetic material is a non-metal magnetic material.

7. The method for fabricating a concentration-gradient high-frequency ferromagnetic film according to claim 6, wherein said non-metal magnetic material is a magnetic oxide material.

8. The method for fabricating a concentration-gradient high-frequency ferromagnetic film according to claim 1, wherein the components of said doping target are selected from the group consisting of metals, oxides, nitrides and borides.
